(19) United States
(12) Patent Application Publication
(10) Pub. No.: US 2007/0159801 A1
(43) Pub. Date: Jul. 12, 2007

(54) Insert molded flexible circuit with stiffener and flip housing assembly and method of manufacture

(75) Inventors: Julio C. Castaneda, Coral Springs, FL (US); Brian B. Belknap, Davie, FL (US); Stephen D. Hunt, Cooper City, FL (US); Francis M. Staszesky, Fort Lauderdale, FL (US); William S. Steinhoff, Plantation, FL (US)

Correspondence Address: AKERMAN SENTERFITT, P.O. BOX 3188, WEST PALM BEACH, FL, 33402-3188, US

(73) Assignee: Motorola, Inc., Schaumburg, IL (US)

(21) Appl. No.: 11/321,289

(22) Filed: Dec. 21, 2005

(51) Int. Cl. H05K 5/00

(52) U.S. Cl. 361/730

(57) ABSTRACT

An electronic product (100) such as a phone includes a base housing assembly (102) and a flip housing assembly (40) coupled to the base housing assembly. The flip housing assembly includes a flexible circuit (10) having an appendage (14) having a hinge contact point, a stiffener (22) adhered to the flexible circuit, a hinge pin (32) formed by insert molding a substantial portion of the appendage to form a flexible circuit assembly (30), and an insert molded housing 42 molded about a substantial portion of the flexible circuit assembly. The base housing assembly and flip housing assembly can electronically couple via the portion of the hinge contact point that remains exposed. The flip housing assembly can include among a lens (52), a transducer (62), a bezel (72), a keypad (82) or a transducer grill (92) mounted on to the flexible circuit assembly.

### FIELD

This invention relates generally to flip housing assemblies, and more particularly to a method and apparatus formed from a flexible circuit and a stiffener.

### BACKGROUND

In an effort to make cellular phones smaller and thinner, flexible circuits have been employed frequently. In particular, flip housing assemblies for clam-shell style products can incorporate flexible circuits but concerns exist about the durability and ruggedness of such arrangements. Additional concerns also exist in terms of ease of manufacture.

### SUMMARY

Embodiments in accordance with the present invention can provide an insert molded flexible circuit with a stiffener that can be utilized in a flip housing assembly.

In a first embodiment of the present invention, a method of creating a flip housing assembly can include the steps of adhering a stiffener to a flexible circuit having a contact point for a main housing to form a flexible circuit assembly, insert molding a hinge pin on the contact point, and insert molding the flexible circuit assembly and hinge pin to form the flip housing assembly. The method can further include adhering one or more among a lens, a transducer, a bezel, a keypad, or a transducer grill cover to the flip housing assembly. The method can further include the step of attaching the contact point to a base housing forming an interconnection between the contact point and circuitry in the base housing. Note, the flexible circuit can be backed with a sheetmetal stiffener or with other suitable materials.

In a second embodiment of the present invention, a flip housing assembly can include a flexible circuit having an appendage having a hinge contact point, a stiffener adhered to the flexible circuit, a hinge pin formed by insert molding a substantial portion of the appendage to form a flexible circuit assembly, and insert molding about a substantial portion of the flexible circuit assembly, wherein at least a portion of the hinge contact point remains exposed. The stiffener can be made of metal, carbon fiber, or other rigid planar materials. The flip housing assembly can further include one or more among a lens, a transducer, a bezel, a keypad or a transducer grill mounted on the flexible circuit assembly.

In a third embodiment of the present invention, an electronic product having a clam-shell style housing (such as for a cellular phone, a smart phone, a camera phone, a laptop computer, a personal digital assistant, a two-way messaging device, or an electronic notebook) can include a base housing assembly and a flip housing assembly coupled to the base housing assembly. The flip housing assembly can include a flexible circuit having an appendage having a hinge contact point, a stiffener adhered to the flexible circuit, a hinge pin formed by insert molding a substantial portion of the appendage to form a flexible circuit assembly, and insert molding about a substantial portion of the flexible circuit assembly so that at least a portion of the hinge contact point remains exposed. As noted above, the stiffener can be made of metal, carbon fiber, or other rigid planar materials. The base housing assembly electronic can couple to the flip housing assembly via the portion of the hinge contact point that remains exposed. The flip housing assembly can further include one or more among a lens, a transducer, a bezel, a keypad or a transducer grill mounted on the flexible circuit assembly.

The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

Other embodiments, when configured in accordance with the inventive arrangements disclosed herein, can include a system for performing and a machine readable storage for causing a machine to perform the various processes and methods disclosed herein.

### BRIEF DESCRIPTION OF THE DRAWINGS

FIG. 1 is an illustration of a flexible circuit used for a flip housing assembly in accordance with an embodiment of the present invention.

FIG. 2 is an illustration of a stiffener adhered to the flexible circuit of FIG. 1 in accordance with an embodiment of the present invention.

FIG. 3 is an illustration of the assembly of FIG. 2 further including an insert molded portion over a hinge pin portion to form a flexible circuit assembly in accordance with an embodiment of the present invention.

FIG. 4 is an illustration of insert molding about a substantial portion of the flexible circuit assembly of FIG. 3 to form the flip housing assembly in accordance with an embodiment of the present invention.

FIG. 5 is an illustration of further including a lens to an outside portion of the flip housing assembly of FIG. 4 in accordance with an embodiment of the present invention.

FIG. 6 is an illustration of further including a transducer with the flip housing assembly of FIG. 5 in accordance with an embodiment of the present invention.

FIG. 7 is an illustration of further including a bezel with the flip housing assembly of FIG. 6 in accordance with an embodiment of the present invention.

FIG. 8 is an illustration of further including a keypad with the flip housing assembly of FIG. 7 in accordance with an embodiment of the present invention.

FIG. 9 is an illustration of further including a transducer grill or grill cover with the flip housing assembly of FIG. 8 in accordance with an embodiment of the present invention.

FIG. 10 is an illustration of an outside portion of the flip housing assembly of FIG. 9 in accordance with an embodiment of the present invention.

FIG. 11 is an electronic product such as a cellular phone in accordance with an embodiment of the present invention.

FIG. 12 is a flow chart illustrating a method of creating a flip housing assembly in accordance with an embodiment of the present invention.

### DETAILED DESCRIPTION OF THE DRAWINGS

While the specification concludes with claims defining the features of embodiments of the invention that are regarded as novel, it is believed that the invention will be better understood from a consideration of the following description in conjunction with the figures, in which like reference numerals are carried forward.

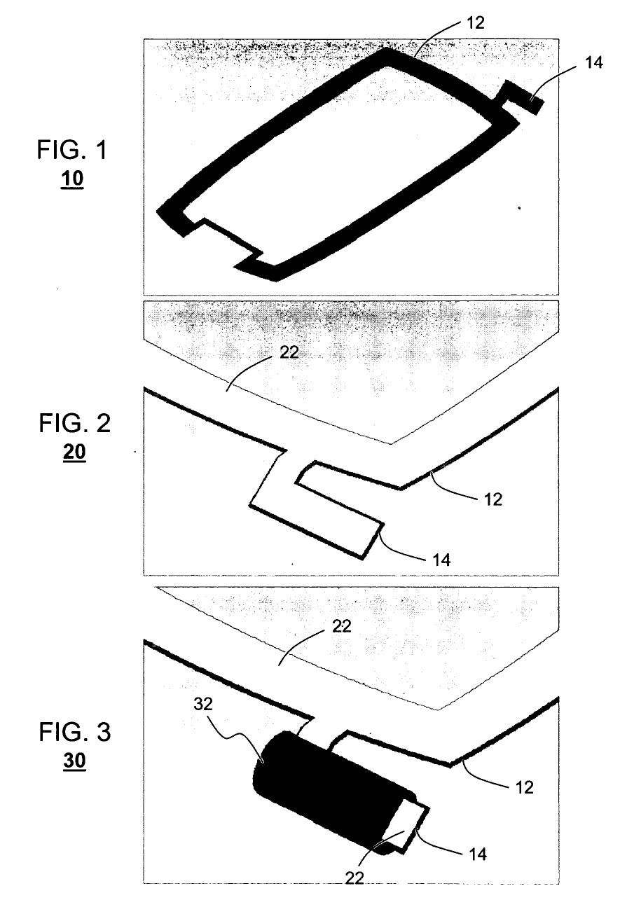

Referring to FIG. 1, a flexible circuit 10 for a flip housing assembly is shown. The flexible circuit 10 can be configured in numerous variations in contemplation of the embodiments herein but generally can include a main portion 12 and a hinge portion or appendage 14. The hinge portion or appendage 14 can include a hinge contact point that serves as a contact between circuitry in a flip housing assembly and circuitry in a base housing assembly as will become apparent. The flexible circuit 10 can be stiffened using a stiffener 22 adhered to the main portion 12 and the hinge portion or appendage 14 as shown in an assembly 20 of FIG. 2. The stiffener 22 can be made of sheetmetal or other suitable rigid materials such as carbon fiber. Referring to FIGS. 2 and 3, the hinge portion or appendage 14 of the assembly 20 can be insert molded to form a hinge pin 32. Thus, the assembly 20 with the molded hinge pin 32 forms a flexible circuit assembly 30.

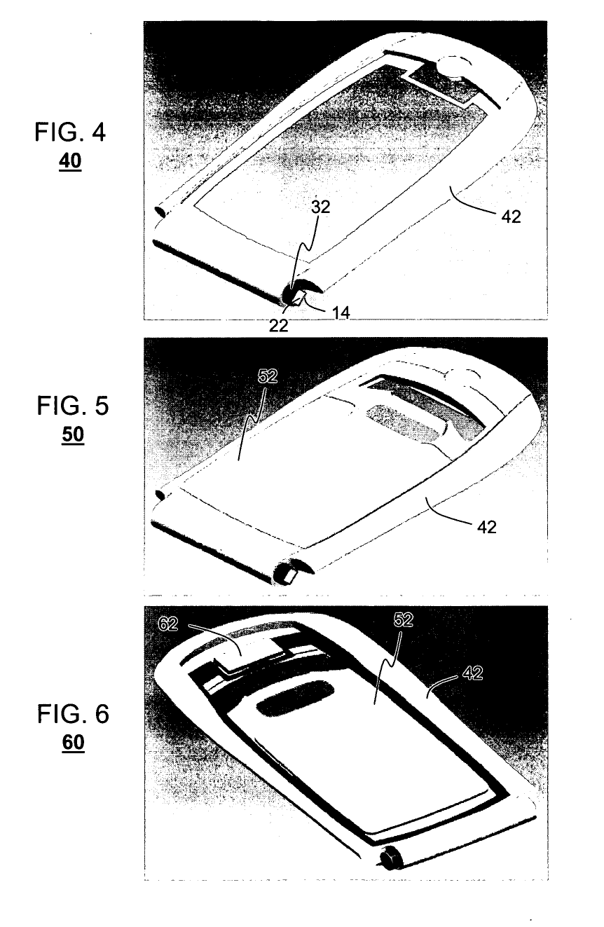

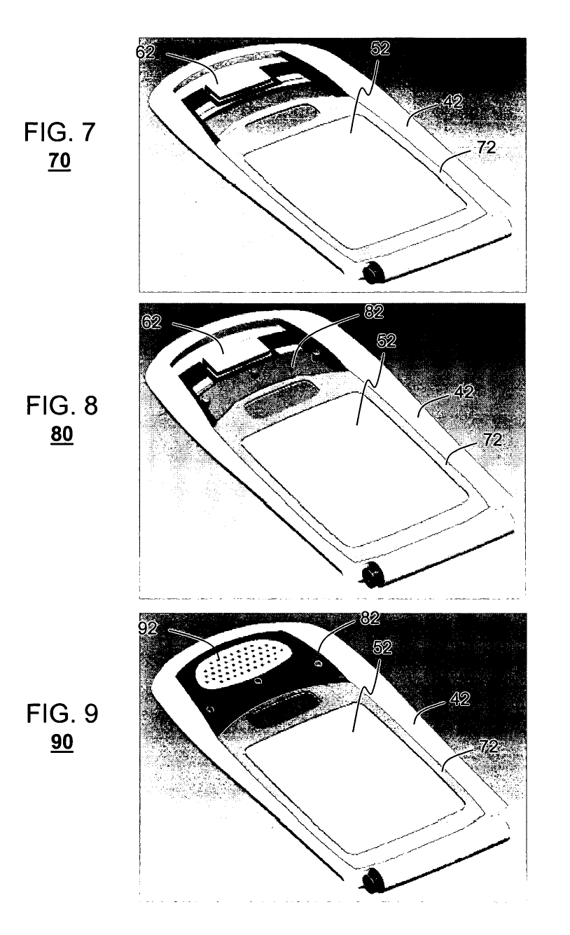

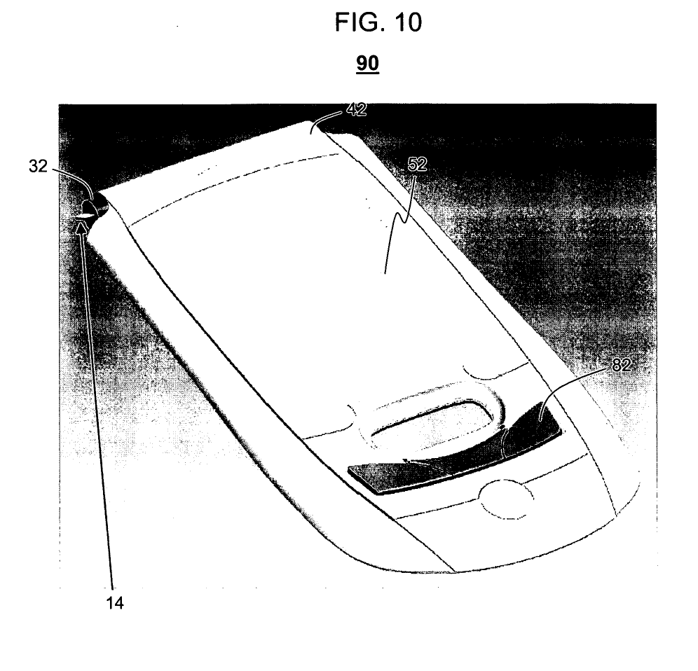

Referring to FIGS. 3 and 4, the flexible circuit assembly 30 can then be substantially insert molded with an insert molded portion 42 as illustrated in FIG. 4 to form the flip housing assembly 40. In the embodiment shown, only a portion of the hinge pin 32 and flexible circuit 10 (or more particularly flexible circuit portion or appendage 14 that has the contact point) is left exposed. On an outside portion of the flip housing assembly 40, a lens 52 can be adhered to the assembly 40 to form assembly 50 of FIG. 5. On an inside portion of the flip housing assembly 40 as illustrated in an assembly 60 of FIG. 6, a transducer 62 can be adhered to the flexible circuit 10. The transducer can be adhered to the flexible circuit 10 by soldering. Next, a bezel 72 can be adhered to the flip housing assembly 40 in an assembly 70 as illustrated in FIG. 7. In FIG. 8, a keypad 82 can be further added to the flip housing assembly 40 to form the assembly 80. The keypad 82 can be press fit into place in a cavity within the flip housing assembly 40 (of FIG. 4). The keypad can also include standoffs or protrusions or nipples that can also assist in maintaining the keypad and other components in place. For example, referring to FIG. 9, a transducer grill or cover 92 can include apertures for mating with the standoffs or protrusions from the keypad 82. The grill or cover 92 along with the other components included in the assembly 80 of FIG. 8 forms the assembly 90 as illustrated in FIG. 9. An outside portion of the assembly 90 is further illustrated in FIG. 10. This outside view illustrates the keypad 82, lens 52, insert molded portion 42, as well as the exposed hinge pin 32 and corresponding hinge potion 14 having the flexible circuit 10.

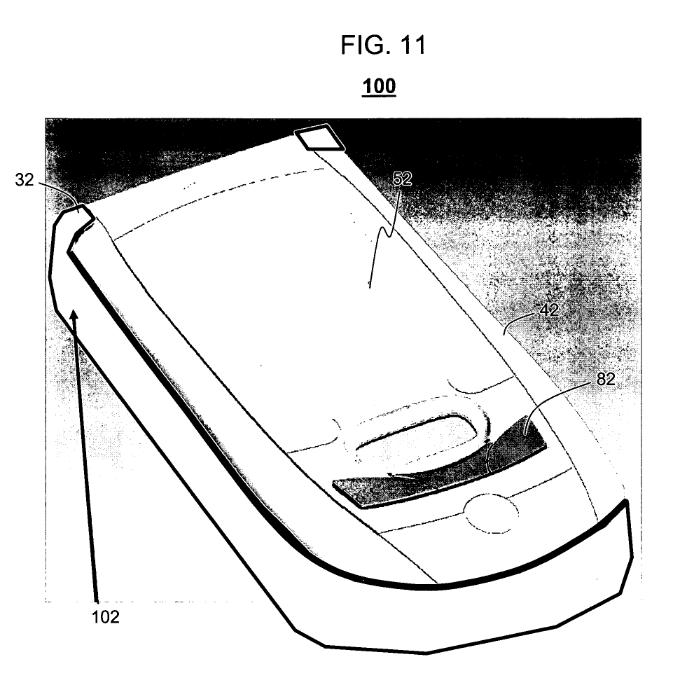

Referring to FIG. 11, a base housing portion 102 can mate with the flip housing portion 40 to form an electronic product 100. The electronic product can be almost any product that can utilize a flip housing assembly as described above including a cellular phone, a smart phone, a camera phone, a laptop computer, a personal digital assistant, a-two-way messaging device, or an electronic notebook as examples. The contact point of the flexible circuit 10 (or 14) can provide the electrical interconnection between circuitry in the flip housing assembly and the base housing assembly. Note, the steps outlined in the description of FIGS. 1-11 above or for the method below are not limited to the particular order in which they are presented. The inventive method can also have a greater number of steps or a fewer number of steps than those shown. Using the techniques described, a thin profiled flip housing with added rigidity (over just using a flexible circuit) can be operatively coupled with a base housing.

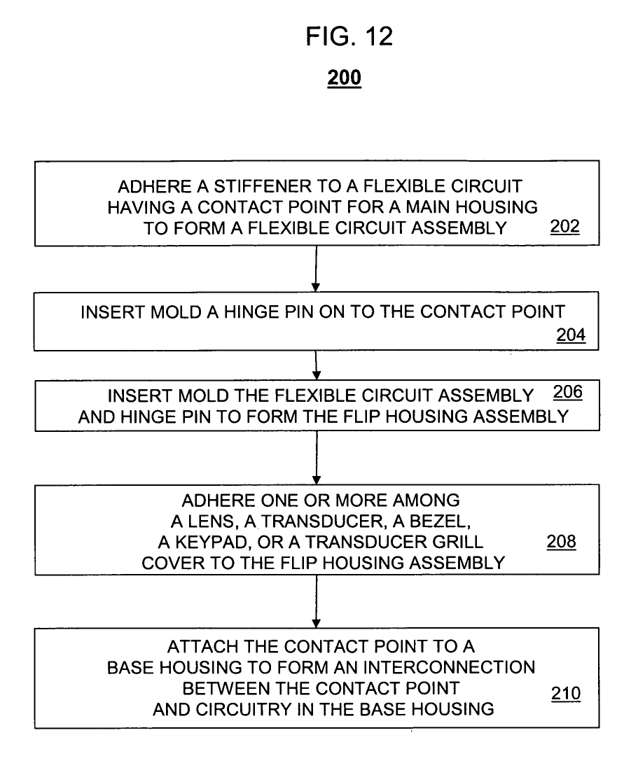

Referring to FIG. 12, a method 200 of creating a flip housing assembly include the step 202 of adhering a stiffener to a flexible circuit having a contact point for a main housing to form a flexible circuit assembly, insert molding a hinge pin on to the contact point at step 204, and insert molding the flexible circuit assembly and hinge pin to form the flip housing assembly at step 206. The method 200 can further include the step 208 of adhering one or more among a lens, a transducer, a bezel, a keypad, or a transducer grill cover to the flip housing assembly. The method 200 can also include the step 210 of attaching the contact point to a base housing forming an interconnection between the contact point and circuitry in the base housing.

In light of the foregoing description, it should also be recognized that embodiments in accordance with the present invention can be realized in numerous configurations contemplated to be within the scope and spirit of the claims. Additionally, the description above is intended by way of example only and is not intended to limit the present invention in any way, except as set forth in the following claims.

What is claimed is:

1. A method of creating a flip housing assembly, comprising the steps of:
adhering a stiffener to a flexible circuit having a contact point for a main housing to form a flexible circuit assembly;
insert molding a hinge pin on to the contact point; and
insert molding the flexible circuit assembly and hinge pin to form the flip housing assembly.

2. The method of claim 1, wherein the method further comprises the step of adhering a lens to an outside portion of the flip housing assembly.

3. The method of claim 1, wherein the method further comprises the step of adhering a transducer to an inside portion of the flip housing assembly.

4. The method of claim 1, wherein the method further comprises the step attaching a bezel to an inside portion of the flip housing assembly.

5. The method of claim 1, wherein the method further comprises the step of attaching a keypad to the flip housing assembly.

6. The method of claim 1, wherein the method further comprises the step of attaching a transducer grill cover to the flip housing assembly.

7. The method of claim 1, wherein the method further comprises the step of attaching the contact point to a base housing forming an interconnection between the contact point and circuitry in the base housing.

8. The method of claim of claim 1, wherein the flexible circuit is backed with a sheetmetal stiffener.

9. A flip housing assembly, comprising:
a flexible circuit having an appendage having a hinge contact point;
a stiffener adhered to the flexible circuit;
a hinge pin formed by insert molding a substantial portion of the appendage to form a flexible circuit assembly; and
insert molding about a substantial portion of the flexible circuit assembly, wherein at least a portion of the hinge contact point remains exposed.

10. The flip housing assembly of claim 9, wherein the stiffener is comprised of metal, carbon fiber, or other rigid planar materials.

11. The flip housing assembly of claim 9, wherein the flip housing assembly further comprises a lens mounted on the flexible circuit assembly.

12. The flip housing assembly of claim 9, wherein the flip housing assembly further comprises a transducer mount on the flexible circuit assembly.

13. The flip housing assembly of claim 9, wherein the flip housing assembly further comprises a bezel mounted on the flexible circuit assembly.

14. The flip housing assembly of claim 9, wherein the flip housing assembly further comprises a keypad mounted on the flexible circuit assembly.

15. The flip housing assembly of claim 9, wherein the flip housing assembly further comprises a transducer grill mounted on the flexible circuit assembly.

16. An electronic product having a clam-shell style housing, comprising:
a base housing assembly; and
a flip housing assembly coupled to the base housing assembly, wherein the flip housing assembly comprises:
a flexible circuit having an appendage having a hinge contact point;
a stiffener adhered to the flexible circuit;
a hinge pin formed by insert molding a substantial portion of the appendage to form a flexible circuit assembly; and
insert molding about a substantial portion of the flexible circuit assembly, wherein at least a portion of the hinge contact point remains exposed.

17. The electronic product of claim 16, wherein the stiffener is comprised of metal, carbon fiber, or other rigid planar materials.

18. The electronic product of claim 16, wherein the base housing assembly electronic couples to the flip housing assembly via the portion of the hinge contact point that remains exposed.

19. The electronic product of claim 16, wherein the flip housing assembly further comprises one or more among a lens, a transducer, a bezel, a keypad or a transducer grill mounted on to the flexible circuit assembly.

20. The electronic product of claim 16, wherein the electronic product comprises a cellular phone, a smart phone, a camera phone, a laptop computer, a personal digital assistant, a two-way messaging device, or an electronic notebook.
